(19) United States
(12) Patent Application Publication
(10) Pub. No.: US 2024/0167482 A1
(43) Pub. Date: May 23, 2024

(54) Computer fan

(71) Applicant: Chien-Hao CHEN, Keelung City (TW)

(72) Inventor: Chien-Hao CHEN, Keelung City (TW)

(21) Appl. No.: 18/149,964

(22) Filed: Jan. 4, 2023

(30) Foreign Application Priority Data
Nov. 18, 2022 (TW) 111144093

(51) Int. Cl. F04D 19/00; F04D 29/26; F04D 29/32; G06F 1/20; H05K 7/20

(52) U.S. Cl. CPC F04D 19/002; F04D 29/263; F04D 29/325; G06F 1/20; H05K 7/20172

(57) ABSTRACT

A computer fan includes a base frame, a fan blade body, and a positioning device. A base plate is arranged on the base frame. A shaft is arranged on the base plate. A through hole is arranged at a central position of the fan blade body for being sleeved on the shaft. The positioning device is for coupling to a top of the shaft, such that the fan blade body is located under the positioning device, and the positioning device is capable of being stabilized and rest on the shaft when the fan blade body is rotating relative to the shaft.

### FIELD OF THE INVENTION

The present invention is related to a computer fan which is simple in structure, low in cost, and can effectively display patterns, texts, or images.

### BACKGROUND OF THE INVENTION

In recent years, the development of computing devices is changing very rapidly. With the evolution of the times, the application of computing devices can be seen everywhere, and it has become what is called a computer today. Computers have a variety of execution and calculation functions, which can meet people's needs. Personal computers are used in family life with functions such as entertainment, word processing, and video playback etc. Industrial computers provide services such as control, supervision, and calculation for factory operations. Car computers provide drivers and passengers with multimedia entertainment and the function of receiving information in real time. Overall, computers have become the indispensable devices for human social life.

Each component in the computer will continuously generate high heat during operations such as calculation, execution, and transmission, and the heat is accumulated in the computer case. Therefore, in order to maintain the stability of computer's operation, in the current home desktop computer, the most common way is to assemble the fan to achieve the cooling effect inside the computer by means of ventilation or exhaust. Since the fan blades of the cooling fan are rotating at high speed, in order to avoid the risk of injury caused by accidental contact, usually, these cooling fans will be installed on the inner side of the opening on the surface of the computer case. Or a layer of protective net will be arranged on the surface of the cooling fan such that a part of the cooling fan will be exposed on the surface of the computer case. In addition, there are not too many design considerations in the design of the fan.

However, in today's market consumption patterns, more and more attention is paid to the visual experience of the assembly of computer peripherals. In addition, in the design of computer case, many popular structural designs such as transparent exteriors and even with lighting are introduced. Therefore, for monotonous fan structure, some manufacturers can combine brand logo and other images on the surface of the fan, but it can only be displayed in a static state, and it cannot be distinguished when the fan is rotating. Therefore, at present, most of them still only match the color and shape of the computer case by combining various lighting of different colors, so that in addition to the original heat dissipation function of the cooling fan, it gradually forms a design to decorate the aesthetics of the computer case.

### SUMMARY OF THE INVENTION

Accordingly, in order to provide a structure different from the conventional technology, the applicant has accumulated many years of experience and continuous research and development, and then the present invention is produced.

The main purpose of the present invention is to provide a computer fan which is simple in structure, low in cost and can effectively display patterns, texts or images.

In order to solve the above described problems and to achieve the expected effect, the present invention provides a computer fan which comprises a base frame, a fan blade body and a positioning device. A base plate is arranged on the base frame. A shaft is arranged on the base plate. A through hole is arranged at a central position of the fan blade body for being sleeved on the shaft. The positioning device is for coupling to a top of the shaft, such that the fan blade body is located under the positioning device, and the positioning device is capable of being stabilized and rest on the shaft when the fan blade body is rotating relative to the shaft.

In implementation, the fan blade body is configured with a depression portion, the through hole is arranged at a central position of the depression portion, the positioning device is capable of being accommodated in the depression portion when the positioning device is coupled to the top of the shaft.

In implementation, a section and a groove are arranged on the top of the shaft, the positioning device comprises a positioning plate, a circlip, and a platform, a plurality of buckle portions are arranged around the positioning plate, a corresponding through hole is arranged at a central position of the positioning plate corresponding to the through hole of the fan blade body, and the corresponding through hole has a corresponding section corresponding to the section on the top of the shaft, such that the positioning plate is capable of being sleeved on the top of the shaft, and the positioning plate is capable of being position-constrained to the top of the shaft by clamping the circlip in the groove, a plurality of corresponding buckle portions are arranged around the platform, such that the platform is capable of being covered on the positioning plate.

In implementation, a concave hole is arranged on a bottom of the platform, the concave hole is for covering on the top of the shaft.

In implementation, a display is arranged on the platform, the display is capable of displaying patterns or texts on the platform by connecting an external circuit to the display.

In implementation, the shaft is a hollow shaft.

For further understanding the characteristics and effects of the present invention, some preferred embodiments referred to drawings are in detail described as follows.

### BRIEF DESCRIPTION OF DRAWINGS

FIG. 1 is the schematic perspective exploded view of an embodiment of computer fan of the present invention.

FIG. 2 is the schematic perspective view of an embodiment of the present invention before positioning device assembled.

FIG. 3 is the schematic perspective view of an embodiment of the present invention before circlip assembled.

FIG. 4 is the schematic perspective view of an embodiment of the present invention after positioning device assembled to shaft.

FIG. 5 is a cross-section schematic of an embodiment of computer fan of the present invention after assembled.

### DETAILED DESCRIPTIONS OF PREFERRED EMBODIMENTS

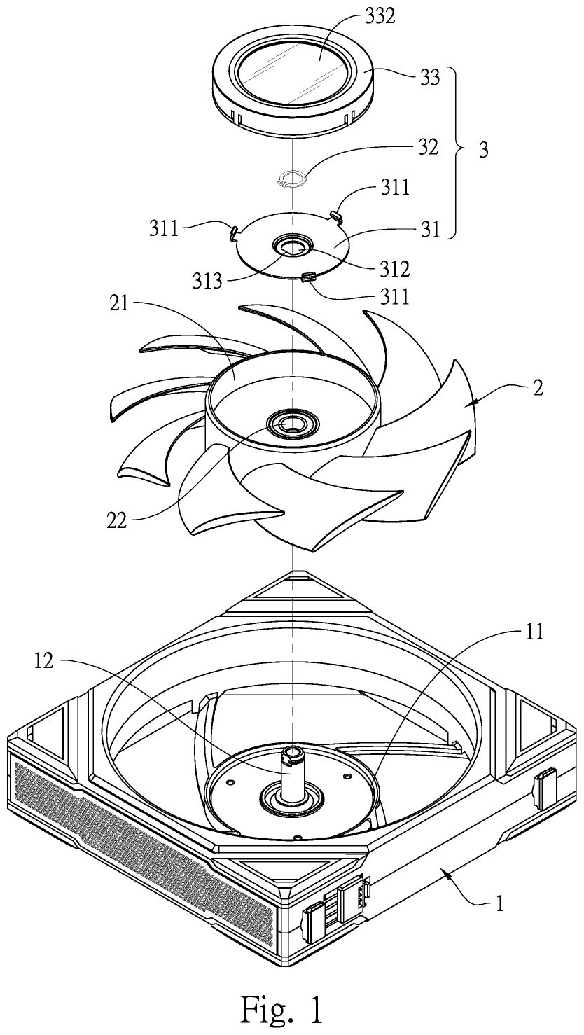

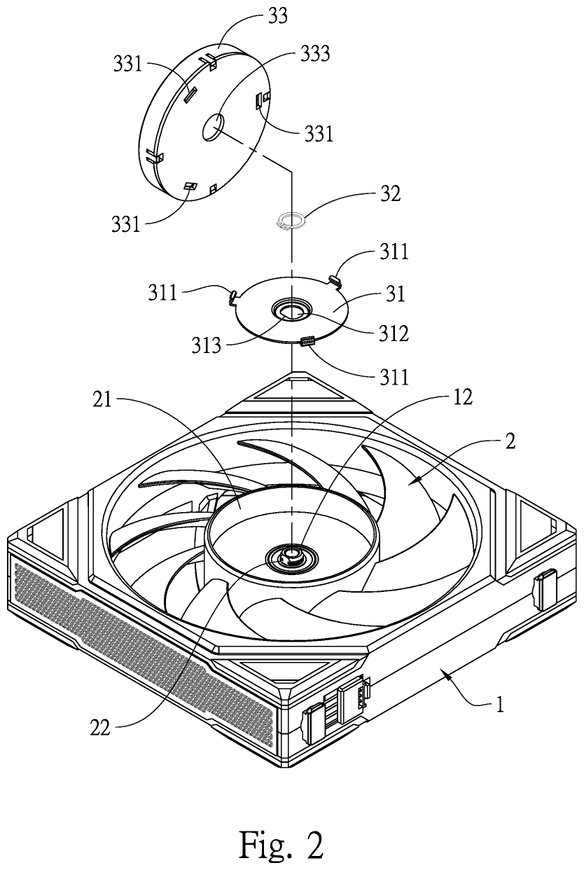

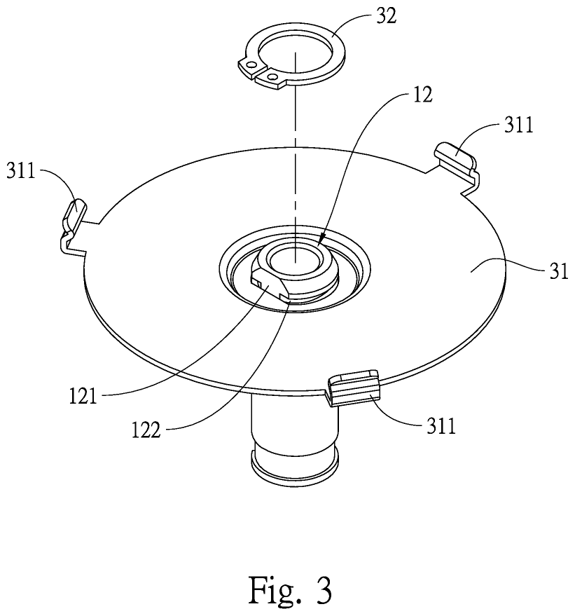

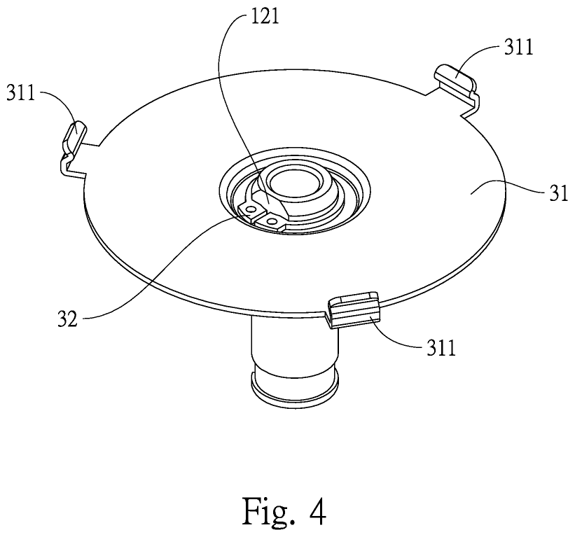

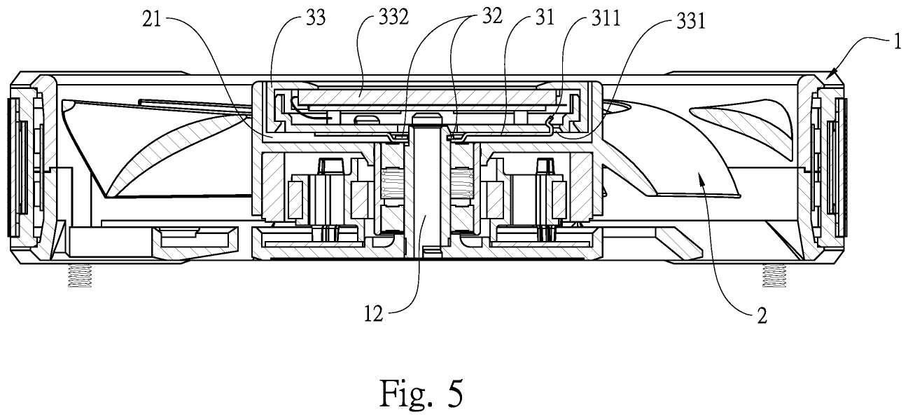

Please refer to FIGS. 1-5, which show an embodiment of computer fan of the present invention. The computer fan comprises a base frame 1, a fan blade body 2 and a positioning device 3.

Abase plate 11 is arranged on the base frame 1. A hollow shaft 12 is arranged on the base plate 11. A section 121 and a groove 122 are arranged on a top of the shaft 12.

The fan blade body 2 is configured with a depression portion 21. A through hole 22 is arranged at a central position of the depression portion 21. The through hole 22 is for being sleeved on the shaft 12.

The positioning device 3 is for coupling to the top of the shaft 12, and the positioning device 3 is capable of being accommodated in the depression portion 21, such that the fan blade body 2 is located under the positioning device 3, and the positioning device 3 is capable of being stabilized and rest on the shaft 12 when the fan blade body 2 is rotating relative to the shaft 12.

The positioning device 3 comprises a positioning plate 31, a circlip 32 and a platform 33. A plurality of buckle portions 311 are arranged around the positioning plate 31. A corresponding through hole 312 is arranged at a central position of the positioning plate 31 corresponding to the through hole 22 of the fan blade body 2. And similarly the through hole 312 has a corresponding section 313 corresponding to the section 121 on the top of the shaft 12, such that the positioning plate 31 is capable of being sleeved on the top of the shaft 12, and the positioning plate 31 is capable of being position-constrained to the top of the shaft 12 by clamping the circlip 32 in the groove 122. A plurality of corresponding buckle portions 331 corresponding to the plurality of buckle portions 311 around the positioning plate 31 are arranged around the platform 33, such that the platform 33 is capable of being covered on the positioning plate 31. Furthermore, a display 332 is arranged on a top of the platform 33, such that the platform 33 is capable of displaying patterns or texts on the platform 33 by connecting an external circuit (the circuit can be routed in the hollow shaft 12) to the display 332. A concave hole 333 is arranged on a bottom of the platform 33, the concave hole 333 is for covering on the top of the shaft 12.

Therefore, in actual implementation, when the through hole 22 of the fan blade body 2 is sleeved on the shaft 12, the fan blade body 2 is capable of being rotating relative to the shaft 12. When the section 313 of the through hole 312 arranged at the central position of the positioning plate 31 is aligned to the corresponding section 121 on the top of the shaft 12, the positioning plate 31 is capable of being sleeved on the top of the shaft 12, and the positioning plate 31 is capable of being position-constrained to the top of the shaft 12 by clamping the circlip 32 in the groove 122. Finally, the platform 33 is covered on the positioning plate 31 and the shaft 12, so that when the fan blade body 2 is rotating, the platform 33 remains stationary.

Thus, the present invention has the following advantages:
1. Through the design of the present invention, when the fan blade body is rotating, the platform can still remain stationary, so that the brand LOGO or any other patterns, texts, or even images can be fully presented without being affected by fan's rotating.
2. The design structure of the present invention is simple and low in cost, which can greatly increase the use value of the fan. For consumers who like transparent (or light-transmitting) computer cases, the fan structure of the present invention can greatly improve appreciation and entertainment of the overall computer appearance.

As disclosed in the above description and attached drawings, the present invention can provide a compute fan. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

1. A computer fan comprising:
a base frame, a base plate arranged on said base frame, a shaft arranged on said base plate, wherein a section and a groove are arranged on a top of said shaft, wherein said shaft has a hollow portion from said top of said shaft through a bottom of said shaft;
a fan blade body having a through hole at a central position of said fan blade body, wherein said through hole is for being sleeved on said shaft; and
a positioning device, said positioning device comprises a positioning plate, a circlip, and a platform, a plurality of buckle portions are arranged around said positioning plate, a corresponding through hole is arranged at a central position of said positioning plate corresponding to said through hole of said fan blade body, and said corresponding through hole has a corresponding section corresponding to said section on said top of said shaft said positioning device is used for coupling to said top of said shaft, such that said fan blade body is located under said positioning device, and such that said positioning plate is sleeved on said top of said shaft, and said positioning plate is position-constrained to said top of said shaft by clamping said circlip in said groove; and a plurality of corresponding buckle portions are arranged around said platform for buckling with said plurality of buckle portions of said positioning plate, such that said positioning plate is covered by said platform, and said positioning device is stabilized and rest on said shaft when said fan blade body is rotating relative to said shaft, wherein a display is arranged on a top of said platform, an external circuit is connected to said display by routing wires inside said hollow portion of said shaft.

2. The computer fan according to claim 1, wherein said fan blade body is configured with a depression portion, said through hole is arranged at a central position of said depression portion, said positioning device is capable of being accommodated in said depression portion when said positioning device is coupled to said top of said shaft.

3-6. (canceled)

7. The computer fan according to claim 16, wherein a concave hole is arranged on a bottom of said platform, and said concave hole is for covering on said top of said shaft.

8. The computer fan according to claim 16, wherein a display is arranged on said platform, and said display is capable of displaying patterns or texts on said platform by connecting an external circuit to said display.

9. (canceled)
